(19) United States
(12) Patent Application Publication
(10) Pub. No.: US 2016/0291090 A1
(43) Pub. Date: Oct. 6, 2016

(54) CONTROL SCHEME CREATION METHOD AND COMPUTER-READABLE RECORDING MEDIUM FOR CREATING CONTROL SCHEME

(71) Applicants: FUJITSU LIMITED, Kawasaki-shi (JP); THE UNIVERSITY OF TOKYO, Tokyo (JP)

(72) Inventors: Tomotake Sasaki, Kawasaki (JP); Hitoshi Yanami, Kawasaki (JP); Junji Kaneko, Mishima (JP); Shinji Hara, Tokyo (JP)

(73) Assignees: FUJITSU LIMITED, Kawasaki (JP); THE UNIVERSITY OF TOKYO, Tokyo (JP)

(21) Appl. No.: 15/061,228

(22) Filed: Mar. 4, 2016

(30) Foreign Application Priority Data
Mar. 30, 2015 (JP) 2015-069976

(51) Int. Cl. G01R 31/36

(52) U.S. Cl. CPC G01R 31/3648; G01R 31/3606

(57) ABSTRACT

A control scheme creation method according to an embodiment includes executing, on a computer, processing of calculation of the amount of stored or released energy of each of a plurality of energy storage devices for each of a plurality of periods based on estimation value information on the amount of energy consumption within a target area and based on remaining amount information representing the amount of remaining energy of each of the plurality of energy storage devices. Furthermore, the control scheme creation method includes executing, on the computer, processing of determination of storage timing or release timing for the energy storage device for each of the periods based on the calculated amount of stored or released energy.

### CROSS-REFERENCE TO RELATED APPLICATION

This application is based upon and claims the benefit of priority of the prior Japanese Patent Application No. 2015-069976, filed on Mar. 30, 2015, the entire contents of which are incorporated herein by reference.

### FIELD

The embodiment discussed herein is related to a control scheme creation method and a computer-readable recording medium for creating control scheme.

### BACKGROUND

In recent years, in view of stabilization of power supply, there has been known techniques of optimally controlling energy supply and demand by using a plurality of energy storage devices (for example, storage battery) provided at each of communities such as buildings, households, and municipalities.

An example of the techniques is a technique in which a server creates a charging/discharging scheme (scheme for selecting any one of options consisting of charge/discharge/bypass) for discrete values related to charging/discharging of each of storage batteries across a plurality of time segments, and distributes to a control device that controls charging/discharging of each of the storage batteries. The control device for each of the storage batteries, based on the distributed control scheme, determines operation of the storage battery in each of the time segments as one of the options consisting of charge/discharge/bypass.

Japanese Laid-open Patent Publication No. 2009-261076

Unfortunately, however, in the above-described conventional technique, operation of the storage battery in each of the time segments of the storage battery is limited to any of the options consisting of charge/discharge/bypass, making it difficult to efficiently utilize capabilities of the energy storage device

### SUMMARY

According to an aspect of an embodiment, a control scheme creation method includes: calculating an amount of stored or released energy of each of a plurality of energy storage devices for each of a plurality of periods, based on estimation value information on an amount of energy consumption within a target area and based on remaining amount information representing an amount of remaining energy of each of the plurality of energy storage devices; and determining storage timing or release timing for each of the energy storage devices in each of the periods based on the calculated amount of stored or released energy.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram illustrating a configuration of a system according to an embodiment;

FIG. 2 is a diagram illustrating a configuration of a storage battery system;

FIG. 3 is an exemplary diagram of a charge command and a discharge command;

FIG. 4 is an exemplary diagram of operation of the storage battery system;

FIG. 5 is an illustration of time and a segment;

FIG. 6 is a diagram illustrating a configuration of a control server according to an embodiment;

FIG. 7 is an exemplary diagram of a node connection configuration;

FIG. 8 is an illustration of a starting time and an ending time;

FIG. 9 is an illustration of definitions of values in the storage battery system;

FIG. 10 is an illustration of definitions of the values in the storage battery system;

FIG. 11 is an illustration of definitions of the values in the storage battery system;

FIG. 12 is a flowchart of exemplary operation of the control server according to an embodiment;

FIG. 13 is a flowchart of exemplary processing of determining charge timing and discharge timing;

FIG. 14 is a flowchart of exemplary processing of determining the charge timing and the discharge timing;

FIG. 15 is an exemplary diagram of a node connection configuration;

FIG. 16 is an illustration of a flow of determining the charge timing and the discharge timing;

FIG. 17 is an illustration of a flow continuing from the flow in FIG. 16;

FIG. 18 is an illustration of a flow continuing from the flow in FIG. 17;

FIG. 19 is a flowchart of exemplary processing of determining the charge timing and the discharge timing;

FIG. 20 is a flowchart of exemplary processing of determining the charge timing and the discharge timing; and

FIG. 21 is an illustration of an exemplary computer that executes a control scheme creation program.

### DESCRIPTION OF EMBODIMENTS

Preferred embodiments of the present invention will be explained with reference to accompanying drawings. In the embodiment, for a configuration having a same function, a same reference sign will be given and overlapping description will be omitted. The control scheme creation method, the control scheme creation program, and the information processing apparatus, described in the embodiments below, are only an example and the embodiments are not limited to this. Moreover, it is possible to combine each of the embodiments appropriately in a scope that does not conflict with each other.

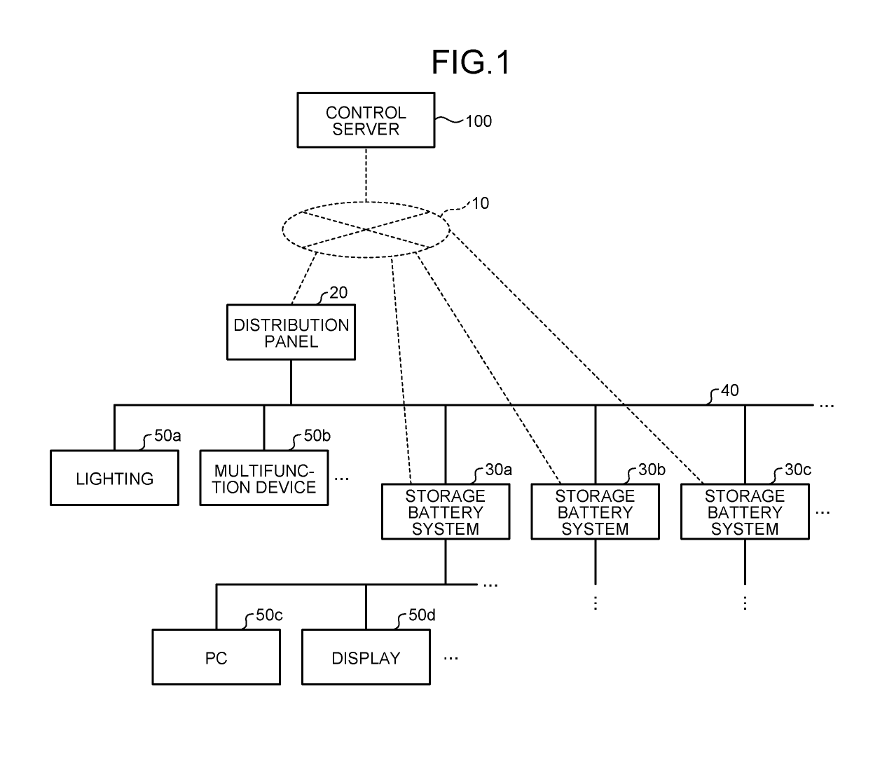

FIG. 1 is a diagram illustrating a configuration of a system according to an embodiment. As illustrated in FIG. 1, the system includes, for example, a distribution panel 20, storage battery systems 30a, 30b, and 30c, lighting 50a, a multifunction device 50b, a personal computer (PC) 50c, a display 50d, and a control server 100. Each of nodes related to energy (power) supply and demand for the distribution panel 20, the storage battery systems 30a, 30b, and 30c, and the lighting 50a and the multifunction device 50b is interconnected with the control server 100, via a network 10. Specifically, the control server 100 is interconnected with each of the power-supply nodes (the distribution panel 20 and the storage battery systems 30a, 30b, and 30c) via the network 10. In addition, each the nodes of the distribution panel 20, the storage battery systems 30a, 30b, and 30c, the lighting 50a, and the multifunction device 50b is connected to a power supply line 40.

The network 10 corresponds to, for example, an intra-company local area network (LAN). As the intra-company LAN, any types of communication networks including a wired LAN and a wireless LAN may be employed. The intra-company LAN may also be connected to other networks including the Internet, and a wide area network (WAN).

In an example in FIG. 1, the control server 100 is connected with each of the nodes of the distribution panel 20, and the storage battery systems 30a, 30b, and 30c, via the network 10. The configuration, however, is not limited to the configuration in FIG. 1. For example, the control server 100 may be connected to any number of nodes.

Moreover, in the example in FIG. 1, the power supply line 40 is connected with components such as the storage battery system 30a, 30b, and 30c, the lighting 50a, and the multifunction device 50b. The configuration, however, is not limited to the configuration in FIG. 1. In other words, it is possible to configure such that the power supply line 40 is connected with any electric appliance. For example, the power supply line 40 may be connected with electric appliances such as a TV, a refrigerator, and a microwave. Hereinafter, the nodes that consume power supplied via the power supply line 40 are classified into the lighting 50a, the multifunction device 50b, and an electric appliance 50 (or load 50) representing the other electric appliances. The electric appliance 50 includes, for example, all products that consume power in a company.

The control server 100 is a server apparatus provided at each of communities such as buildings, households, and municipalities. In the present embodiment, a stand-alone server apparatus is described as an example of the control server 100. Alternatively, the control server 100 may be a virtual machine that is implementable in cooperation with server apparatuses distributed on a network and that is configured in a cloud environment. The control server 100 creates a control scheme to define charging/discharging of the storage battery systems 30a, 30b, and 30c, based on an estimation value of power demand on the electric appliance 50 and on a battery remaining amount (also referred to as remaining amount) of the storage battery systems 30a, 30b, and 30c. The distribution panel 20 supplies power (for example, power of commercial power supply) input from an external power supply system to the storage battery systems 30a, 30b, and 30c, and to the electric appliance 50, via the power supply line 40.

In order to stably supply power to the electric appliance 50 (the PC 50c and the display 50d in an illustration) connected to the own system, each of the storage battery systems 30a, 30b, and 30c stores power input via the power supply line 40, or releases stored power to the electric appliance 50 according to the control scheme created by the control server 100. Hereinafter, in a case where no distinction is needed, the storage battery systems 30a, 30b, and 30c are described collectively as a storage battery system 30.

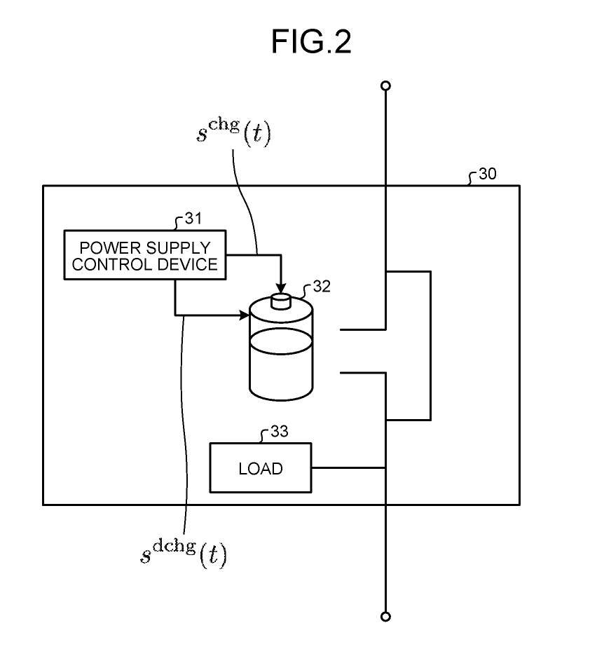

FIG. 2 is a diagram illustrating a configuration of the storage battery system 30. As illustrated in FIG. 2, the storage battery system 30 includes a power supply control device 31, a storage battery 32 and a load 33. According to the control scheme created by the control server 100, the power supply control device 31 outputs a charge command (s^{chg} (t)), and a discharge command (s^{dchg} (t)) so as to control charging/discharging on the storage battery 32.

The storage battery 32 is a secondary battery that stores power that is input via the power supply line 40 and releases the stored power to the power supply line 40, in response to a charge command and a discharge command. Specifically, the storage battery 32 includes an AC/DC converter and a DC/AC converter, and charges the secondary battery in response to the charge command (converter operation command) that is input to the AC/DC converter. In addition, the storage battery 32 discharges from the secondary battery in response to the discharge command (converter operation command) that is input to the DC/AC converter. The load 33 is an electric devices (for example, a cooling fan) operating on the storage battery system 30.

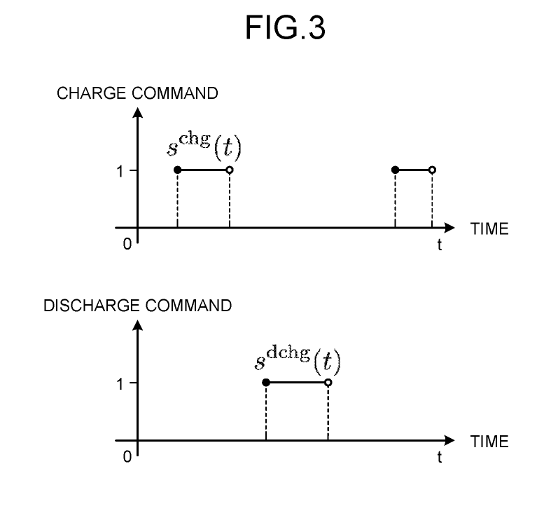

FIG. 3 is an exemplary diagram of the charge command (s^{chg} (t)) and the discharge command (s^{dchg} (t)). As illustrated in FIG. 3, each of the charge command (s^{chg} (t)) and the discharge command (s^{dchg} (t)) represents a time function with values of {0 (non-operating), 1 (operating)}.

The AC/DC converter of the storage battery 32 operates and charges the storage battery 32 at the time (timing) when the charge command (s^{chg} (t)) is {1}. When the charge command is {0}, operation of the AC/DC converter is suspended and charging of the storage battery 32 is then suspended. Similarly, the DC/AC converter of the storage battery 32 operates at the timing that the discharge command (s^{dchg} (t)) is {1}. At the timing that the discharge command is {0}, operation of the DC/AC converter is suspended and discharging from the storage battery 32 is performed at the timing that the discharge command is {1}.

Hereinafter, the charge command (s^{chg} (t)) will be also referred to as charge timing, and the discharge command (s^{dchg} (t)) will be also referred to as discharge timing. In the present embodiment, to create a control scheme related to charging/discharging of the storage battery system 30 is to determine ultimately the charge timing and the discharge timing.

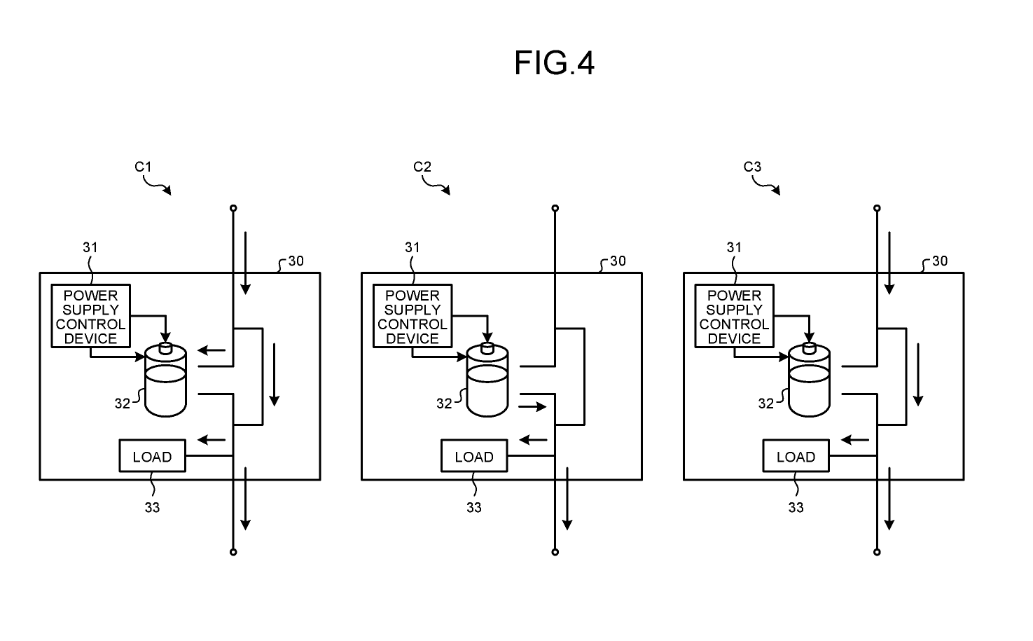

FIG. 4 is an exemplary diagram of operation of the storage battery system. As illustrated in FIG. 4, in a case C1 where the charge command (s^{chg} (t)) is {1} and charging of the storage battery 32 is performed, charging of the storage battery 32 using the input power, and bypassing are performed. Hereinafter, a case where charging and bypassing are performed on the input power will be simply represented as charging.

In a case C2 where the discharge command (s^{dchg} (t)) is {1} and charging of the storage battery 32 is performed, discharging from the storage battery 32 is performed. In a case C3 where the charge command (s^{chg} (t)) and the discharge command (s^{dchg} (t)) are {0} and thus no charging/discharging of the storage battery 32 is performed, bypassing of the input power is performed. The storage battery system 30 performs any one operation of the cases C1 to C3 in response to the charge command (s^{chg} (t)) and the discharge command (s^{dchg} (t)).

The present embodiment has illustrated an exemplary stationary-type configuration in which the storage battery system 30 includes an AC/DC converter and a DC/AC converter and performs charging of the power supplied from the power supply line 40 and discharging of the charged power to the electric appliance 50. The storage battery system 30, however, may be an electric device that performs charging of the power supplied from the power supply line 40 and that uses the charged power on its own device. Specifically, the storage battery system 30 may be a notebook PC including the storage battery 32. For example, in a case of the notebook PC, discharging in the above-described case C2 means consumption on the load such as a processor within the own device.

Creation of the control scheme related to charging/discharging of the storage battery system 30 is determined for each of predetermined periods of time (each of time segments). Herein, an exemplary time and segment related to creation of the control scheme will be defined.

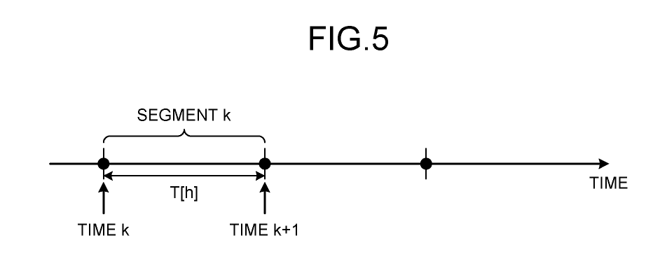

FIG. 5 is an illustration of time and a segment. In FIG. 5, a time axis is written so as to progress in a left to right direction. Hereinafter, an arbitrary point on this time axis is referred to as a time point. Hereinafter, a reference time point is referred to as time 0, in some cases, a time point at a shifted position in a right direction for a predetermined time width T (a time point at a shifted position in the future for a time width T) is referred to as time (discrete time) 1, time (discrete time) 2, time (discrete time) 3, or the like. An interval between the time k and the time k+1 which is located a time width T from the time k is determined as a segment K. In the present embodiment, power demand estimation and control scheme creation on the control server 100 is configured to be performed for the segment K. For example, demand estimation on and after the segment K, and acquisition of information needed for creating the control scheme is configured to start at the time k(=time point kT). Note that the time needed for demand estimation and information acquisition is considered to be negligible compared with the time width T. In some cases, the time width T may be referred to as a unit time width T.

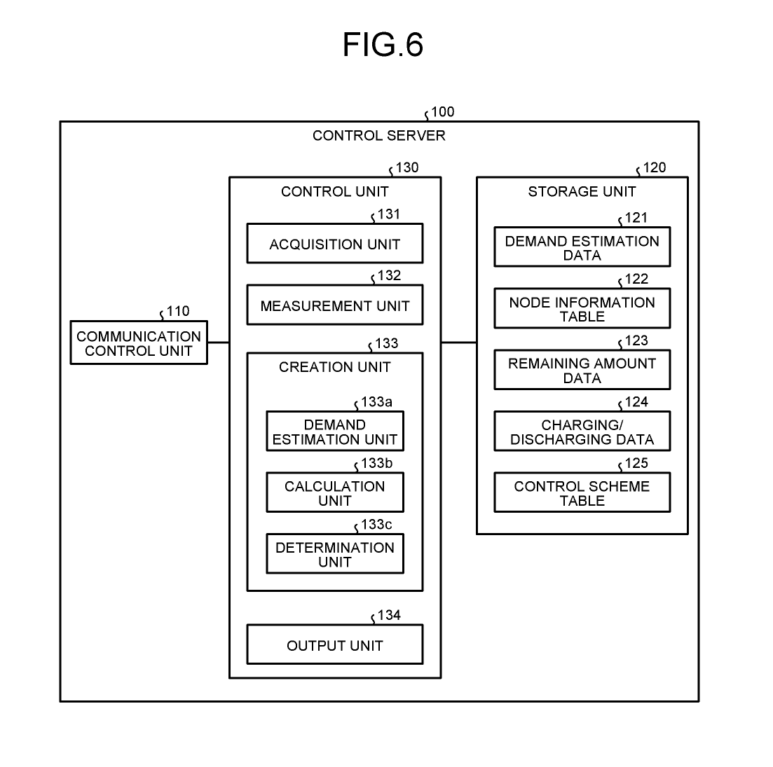

FIG. 6 is a diagram illustrating a configuration of the control server 100 according to an embodiment. As illustrated in FIG. 6, the control server 100 includes a communication control unit 110, a storage unit 120, and a control unit 130.

The communication control unit 110 is a processing unit that is configured to transmit/receive data between the nodes such as the distribution panel 20 and the storage battery system 30. The communication control unit 110 corresponds to, for example, a network interface card (NIC). The control unit 130 exchanges data with the nodes such as the distribution panel 20 and the storage battery system 30, via the communication control unit 110.

The storage unit 120 stores demand estimation data 121, a node information table 122, remaining amount data 123, charging/discharging data 124, and a control scheme table 125. The storage unit 120 corresponds to, for example, a semiconductor memory device such as random access memory (RAM), read only memory (ROM), flash memory, and a storage device such as a hard disk drive (HDD).

The demand estimation data 121 are time series data representing power demand estimated within a system. For example, the demand estimation data 121 are data that have associated each of the time zones (each of segments K) in a day and a power demand value. The power demand value for each of the time zones is calculated by a demand estimation unit 133a and stored in the demand estimation data 121.

The node information table 122 retains various types of information related to each of the nodes (the distribution panel 20, the storage battery system 30, and the electric appliance 50) connected to the power supply line 40, within a system. Specifically, the node information table 122 retains, for each of identification information (ID) representing each of the nodes, constants at the node, information allocated to the node beforehand, and information representing a connection relationship between the nodes. The constants at the node include, for example, constants for the node (for example, a rated output power value, the rated power consumption value, the full charge capacity) that are referenced when a calculation unit 133b or a determination unit 133c performs computation.

Assuming that each of the distribution panel 20, the storage battery system 30, and the electric appliance 50 is each of the nodes, and that the power supply line 40 is an edge, connection of each of the nodes can be described to have a tree structure in which the distribution panel 20 close to the power supply system that supplies power from an external source functions is determined as the root node. In this structure, it is assumed that the direction of power supply has been determined as the direction that starts on the root node and is directed to an end. Based on the direction of power supply, it is assumed that a portion from the own node to the root node is determined as “upstream” and a portion from the own node to the end is determined as “downstream”. As stated in the following definition (1), an index has been allocated to each of the nodes in advance. The index indicates a depth from the root node as a starting point to the end.

It is assumed that an index (i, j), in which the depth is determined as a first element, is allocated to each of nodes A set of all existing (i, j) is represented as N. (1)

The index described in definition (1) is retained in the node information table 122 as information that has been allocated to each of the nodes in advance. The node information table 122 retains information representing an inter-node connection relationship using this index, or the like.

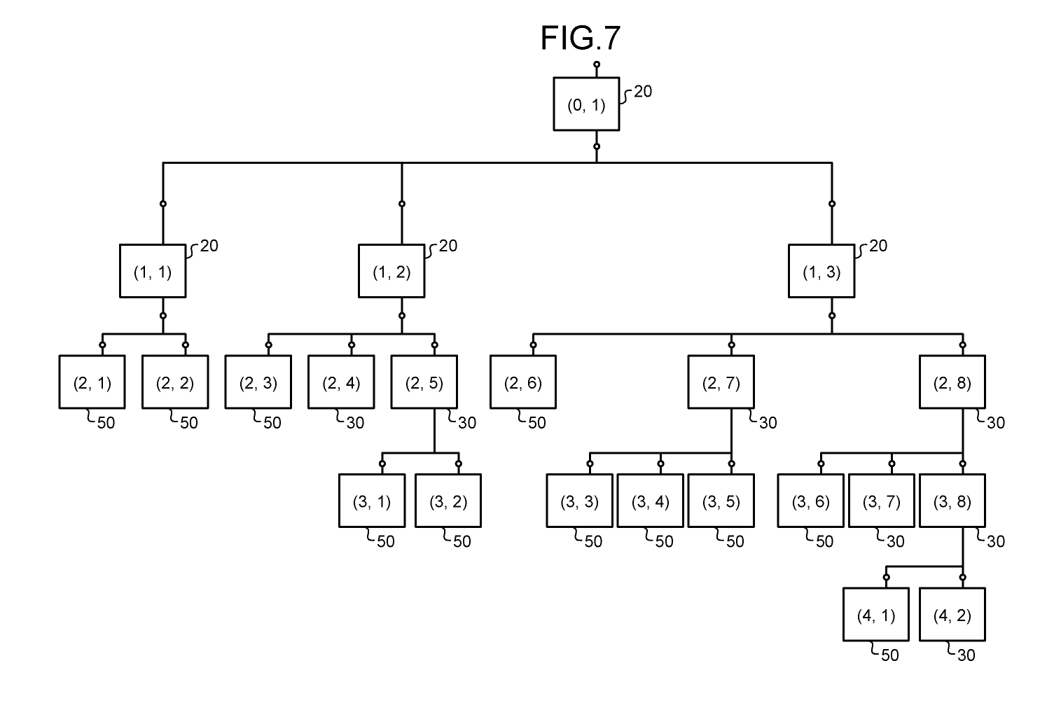

FIG. 7 is an exemplary diagram of a node connection configuration. As illustrated in FIG. 7, the configuration has a tree structure ranging from an energy-supplying node in a system (distribution panel 20 (0, 1)) to an energy-consuming nodes in a system (the storage battery system 30 (in case of notebook PC) or the electric appliance 50), having the distribution panel 20 and the storage battery system 30 sandwiched in between.

To each of the node, an index (i, j) in which a depth is determined as a first element, is allocated. In addition, for each of the nodes, connection relationship information such as {index of the node connected to the upstream|index of the node connected to the downstream} is retained on the node information table 122. Specifically, for the node (1, 1), information such as {upstream: (0, 1)|downstream: (2, 1), (2, 2)} is retained. Accordingly, with reference to the index and connection relationship of each of the nodes, it is possible to detect a node that is close to an energy-consuming node (a node that has a long depth from the root node to the end).

Herein, a node (n) with an index, and a set of nodes within a system, are defined in (2) below.

$$\begin{matrix}A node with the index ( i , j ) is represented as {n}_{i , j} , \\ regardless of the type . \\ Expression of the node ni , j and the node ( i , j ) are used \\ appropriately . \\ A set of all child nodes of the node {n}_{i , j} is \\ represented as {C}_{i , j} . \\ ( “ C ” is a letter for child ) \\ A set of all descendent nodes of the node {n}_{i , j} is \\ represented as {D}_{i , j} . \\ ( “ D ” is a letter for descendent ) \\ A set of all ancestor nodes of the node {n}_{i , j} is \\ represented as {A}_{i , j} . \\ ( “ A ” is a letter for ancestor ) \\ A set of the node {n}_{i , j} itself and all descendent \\ nodes of the node {n}_{i , j} is represented as {F}_{i , j} . \\ {F}_{i , j} = \{ {n}_{i , j} \} ⋃ {D}_{i , j} \end{matrix} \} \qquad ( 2 )$$

In addition, a set of devices with a storage battery system such as a stationary storage battery system and a notebook PC in the storage battery system 30, is defined as in (3) below.

$$\begin{matrix}A set of all of stationary storage battery systems and its \\ descendent nodes and devices with the storage battery system \\ is represented as {F}_{batt} . \\ The formula \\ would be \text{:} {F}_{batt} = {⋃}_{i , j \text{:} {n}_{i , j} ∈ B} {F}_{i , j} \end{matrix} \} \qquad ( 3 )$$

The remaining amount data 123 are data that are used to manage the remaining amount (battery remaining amount) of each of the storage battery systems 30. The remaining amount data 123 are configured to be stored such that the remaining amount of the storage battery 32 is stored for each of identification information (for example, ID) indicating the storage battery system 30. The remaining amount of the storage battery system 30 is obtained from an acquisition unit 131 and stored to the remaining amount data 123.

The charging/discharging data 124 are data for managing information related to charging/discharging of each of the storage battery systems 30. The charging/discharging data 124 include, for example, data that associate a charge/discharge rate with charging/discharging time at a time of charging/discharging on the storage battery 32, for each of IDs indicating each of the storage battery systems 30.

The control scheme table 125 retains information for controlling charging/discharging of each of the storage battery systems 30 for a predetermined period (time segment), in operation time of a system that includes the storage battery system 30 in which the control server 100 controls charging/discharging. Specifically, the control scheme table 125 retains, for each of the segments in operation time (starting time to ending time) of the system, an ID indicating the storage battery system 30 and charge timing/discharge timing of the storage battery system 30. Values for the charge timing and the discharge timing are determined by a creation unit 133 and the values are stored in the control scheme table 125.

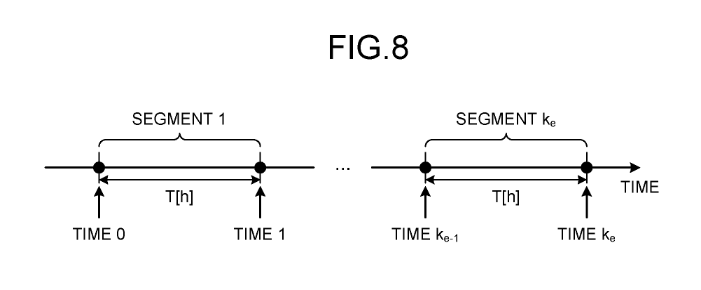

FIG. 8 is an illustration of starting time and ending time. As illustrated in FIG. 8, it is assumed that the operation time of the system starts at a starting time of 0 and ends at an ending time of kₑ. The control scheme table 125 retains charge timing and discharge timing on each of the storage battery systems 30, for segments 1 to kₑ that is from the starting time of 0 to the ending time of kₑ.

The control unit 130 includes the acquisition unit 131, a measurement unit 132, the creation unit 133, and an output unit 134. The control unit 130 corresponds to an integrated device such as an application specific integrated circuit (ASIC) and a field programmable gate array (FPGA). The control unit 130 corresponds to, for example, an electronic circuit such as a CPU and a micro processing unit (MPU).

The acquisition unit 131 is a processing unit that obtains various types of information related to each of the nodes within a system (the distribution panel 20, the storage battery system 30, and the electric appliance 50) connected to the power supply line 40, and that registers obtained information to the node information table 122. Specifically, the acquisition unit 131 receives operation performed on a registration screen displayed on a display unit (not illustrated) from an input device such as a keyboard and a mouse, so as to obtain information related to each of the nodes. Alternatively, it is possible to configure such that the acquisition unit 131 obtains information related to each of the nodes by performing inquiry on the information to a control device of each of the nodes. The acquisition unit 131 adds identification information (for example, ID) for identifying nodes to the obtained information related to each of the nodes, and then registers the combined information onto the node information table 122.

The acquisition unit 131 is a processing unit that obtains a remaining amount (battery remaining amount) of each of the storage battery systems 30 within a system connected to the power supply line 40 and that registers the obtained remaining amount of each of the storage battery systems 30 onto the remaining amount data 123. Specifically, the acquisition unit 131 performs an inquiry about the remaining amount to the power supply control device 31 of each of the storage battery systems 30, and after adding identification information (for example, ID) for node identification, to the remaining amount obtained with this inquiry, registers the combined information onto the remaining amount data 123.

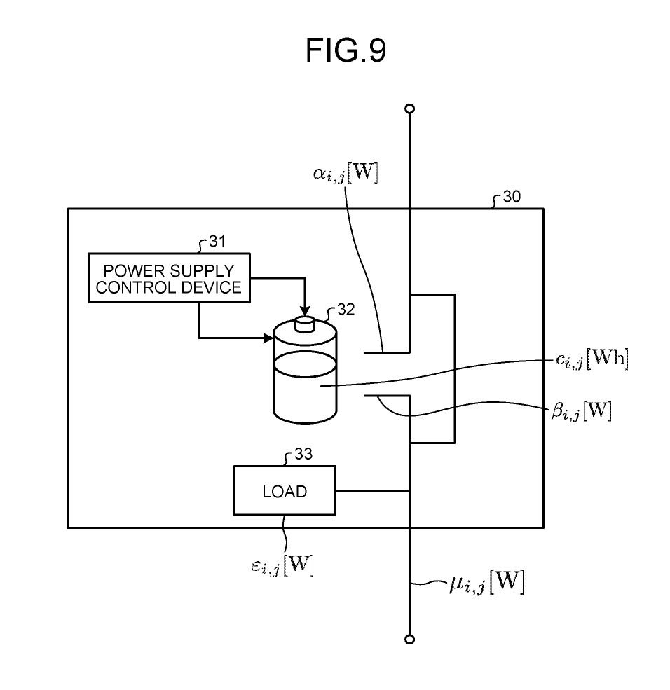

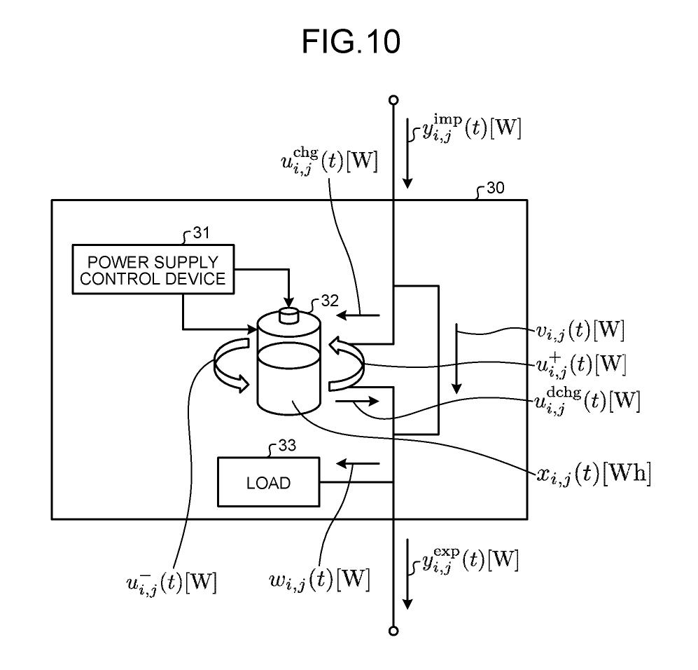

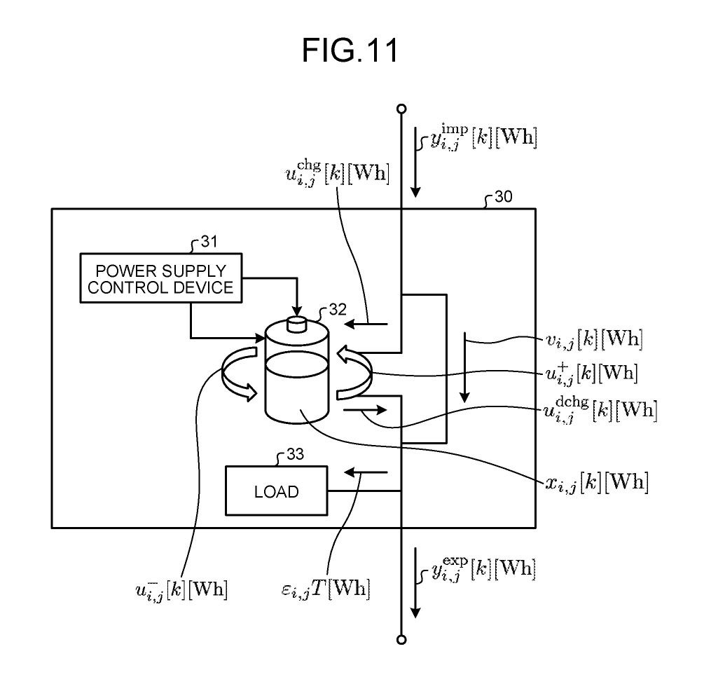

Definition of values (for example, the remaining amount of the storage battery system 30) in each of the nodes will be described. FIGS. 9 to 11 illustrate definitions of values in the storage battery system 30. Specifically, FIG. 9 is a diagram describing a definition related to performance of the storage battery system 30. FIG. 10 is a diagram illustrating definitions of values related to the time point t. FIG. 11 is a diagram illustrating definitions of values related to the segment K from the time k to the time k+1.

As illustrated in FIG. 9, α_{i, j}[W] is a power value used at charging. β_{i, j}[W] represents a rated output power value of the storage battery 32 (including a DC/AC converter). c_{i, j}[Wh] represents a full charge capacity of the storage battery 32. ε_{i, j}[W] represents a rated power consumption value of the load 33. μ_{i, j}[W] represents a rated output power value (maximum output power value) of the storage battery system 30. α_{i, j}, β_{i, j}, c_{i, j}, ε_{i, j}, μ_{i, j}≧0, β_{i, j}≧ε_{i, j}+μ_{i, j} is established. These values are stored on the node information table 122 as, for example, information related to the storage battery system 30.

The term “rated” in the rated output power value and the rated power consumption value represents an ensured usage limitation on an electric device. The “rated” value defines a usage limitation for the output, specifies power, rotation speed, frequency, or the like, respectively, as a rated output power, a rated rotation speed, and a rated frequency, or the like. The electric appliance 50 is designed such that the electric appliance 50 with the rated power consumption of 60 [W] has a power consumption of 54 [W], which is approximately 90% of the rated power consumption.

As illustrated in FIG. 10, y_{i, j}^{imp} (t)[W] is a power value to be incorporated into the storage battery system 30 at a time point t. u_{i, j}^{chg} (t) [W] represents a power value used for charging at the time point t. u_{i,j}⁺(t)[W] represents a remaining amount change rate of the storage battery 32 by charging at the time point t. u_{i, j}⁻(t)[W] represents a remaining amount change rate of the storage battery 32 by discharging at the time point t. _{i, j}^{dchg} (t)[W] represents a power value discharged at the time point t. w_{i, j} (t)[W] represents a power consumption value of the load 33 at the time point t. v_{i, j} (t)[W] represents a power value bypassed at the time point t. x_{i, j} (t)[Wh] represents a remaining amount of the storage battery 32 at the time point t. y_{i, j}^{exp} (t)[W] represents a power value that is output from the storage battery system 30 at the time point t. These values are stored, for example, in the node information table 122 and the remaining amount data 123 when the acquisition unit 131 obtains the values at the time point t as the information related to the storage battery system 30.

As illustrated in FIG. 11, y_{i, j}^{imp} (k) [Wh] is the amount of power incorporated into the storage battery system 30 in the segment K. u_{i, j}^{chg} (k)[Wh] represents the amount of power used for charging in the segment K. u_{i, j}⁺(k)[Wh] represents the remaining amount of the storage battery 32 that is increased by charging in the segment K. u_{i, j}⁻(k)[Wh] represents the remaining amount of the storage battery 32 that is decreased by discharging in the segment K. u_{i, j}^{dchg} (k) [Wh] represents the amount of power that is discharged in the segment K. ε_{i, j}T[Wh] represents a maximum value of power consumption amount of the load 33 in the segment K. v_{i, j} (k)[Wh] represents the amount of power bypassed in the segment K. x_{i, j} (k)[Wh] represents the remaining amount of the storage battery 32 at the time k. y_{i, j}^{exp} (k)[Wh] represents the amount of power that is output from the storage battery system 30 in the segment K.

In examples in FIGS. 9 to 11, types of node (i, j) are illustrated as nodes for the storage battery system 30. For the distribution panel 20 and the electric appliance 50, it is configured to use the same types uniformly. Note that, for the distribution panel 20 and the electric appliance 50, values related to charging/discharging are not to be defined; values such as power consumption on a load and bypassed power are to be defined.

The measurement unit 132 measures the amount of power consumed within a system. The measurement unit 132 outputs information of the measured power consumption amount to the creation unit 133.

The measurement unit 132 measures, for example, the total amount of power consumed within a company, by the electric appliances 50 connected to the power supply line 40. The measurement unit 132 records information of the measured amount of power in the storage unit 120. Illustration of the information of the power to be stored in the storage unit 120 will be omitted. A method for measuring the amount of power consumed within a company by using the measurement unit 132 is applicable to any conventional techniques. For example, the measurement unit 132 may be configured such that the distribution panel 20 measures the amount of power supplied via the power supply line 40 and obtains the measured amount of power from the distribution panel 20. Alternatively, the measurement unit 132 may be configured, for example, to measure the amount of power supplied from all outlets in a company so as to calculate the sum. Alternatively, the measurement unit 132 may be configured, for example, to obtain the amount of power consumed on each of the nodes by transmitting an inquiry to a control device of the node, and to calculate the sum of the obtained amount of power.

The creation unit 133 is a processing unit that includes the demand estimation unit 133a, the calculation unit 133b, and the determination unit 133c, and performs processing of creating the control scheme table 125.

The demand estimation unit 133a, based on the amount of power consumed within a system, that has been measured by the measurement unit 132, and on weather information, or the like, that is input from an external distribution server (not illustrated), calculates an estimation value of the power demand amount within a system (the estimated amount of power consumption). Calculation of the estimation value of the power demand amount is performed by a known power demand amount estimation technique. The weather information according to the present embodiment includes temperature information such as external temperature and room temperature. Parameters to be referred to when the estimation value of the power demand amount (the amount of power to be consumed and to be estimated) are calculated may be, for example, date and time. The parameters are not limited in particular.

The calculation unit 133b calculates the amount of charging/discharging of each of the storage battery systems 30 for a plurality of future time segments based on the estimation value of the power demand amount within a system calculated by the demand estimation unit 133a, and based on the remaining amount of each of the storage battery systems 30 stored in the remaining amount data 123. Specifically, the calculation unit 133b calculates the amount of charging/discharging of each of the storage battery systems 30 for each of the segments K across the segment 1 to kₑ that corresponds to the above-described starting time of 0 to the ending time of kₑ.

For example, the calculation unit 133b, in each of the time segments, solves an optimization problem that minimizes an objective function including a peak power consumption amount based on the estimation value of the power demand amount. Accordingly, the calculation unit 133b calculates the amount of power to be used for charging each of the storage battery systems 30 and a real number value of the amount of discharged power. It is possible to configure such that the calculation unit 133b solves the above-described optimization problem in each of the time segments and then calculates the increasing or decreasing amount of the remaining amount of each of the storage battery systems 30, or calculates the real number value of the total time of charging or discharging by each of the storage battery systems 30. Known software for obtaining the real number value by solving an optimization problem as above is easily available. Accordingly, it is possible to configure such that the calculation unit 133b solves the optimization problem by using the known software.

Detailed calculation processing of the calculation unit 133b will be described. A model expression of a node (i, j) in the segment K is described in the following Expression (4).

$$\begin{matrix}{x}_{i , j} [ k + 1 ] = {x}_{i , j} [ k ] + {u}_{i , j}^{+} [ k ] - {u}_{i , j}^{-} [ k ] \\ 0 \leq {u}_{i , j}^{+} [ k ] , 0 \leq {u}_{i , j}^{-} [ k ] \\ 0 \leq {u}_{i , j}^{chg} [ k ] , 0 \leq {u}_{i , j}^{dchg} [ k ] \\ 0 \leq {ν}_{i , j} [ k ] 1 \\ {x}_{i , j} [ {k}_{s} ] = {x}_{i , j}^{s} \\ 0 \leq {x}_{i , j} [ k ] + {u}_{i , j}^{+} [ k ] - {u}_{i , j}^{-} [ k ] \leq {c}_{i , j} \\ {β}_{i , j} {u}_{i , j}^{chg} [ k ] + {α}_{i , j} {u}_{i , j}^{dchg} [ k ] \leq {α}_{i , j} {β}_{i , j} T \\ {y}_{i , j}^{imp} [ k ] = {u}_{i , j}^{chg} [ k ] + {ν}_{i , j} [ k ] \\ {y}_{i , j}^{exp} [ k ] = {u}_{i , j}^{dchg} [ k ] + {ν}_{i , j} [ k ] - {ɛ}_{i , j} T \\ {u}_{i , j}^{+} [ k ] = {η}_{i , j}^{chg} [ k ] {u}_{i , j}^{chg} [ k ] \\ {u}_{i , j}^{dchg} [ k ] = {η}_{i , j}^{dchg} {u}_{i , j}^{-} [ k ] \\ {y}_{i , j}^{exp} [ k ] \leq {μ}_{i , j} T \\ {y}_{i , j}^{exp} [ k ] = {\sum }_{l , m \text{:} {n}_{l , m} ∈ {e}_{i , j}} {y}_{l , m}^{exp} [ k ] \end{matrix} \} \qquad ( 4 )$$

The type of node (i, j) in Expression (4) is the storage battery system 30 illustrated in FIG. 11. Note that each of the expressions is followed by k=1, . . . , kₑ or k=0, . . . kₑ₋₁, although it is omitted in Expression (4). x_{i, j}^{s} is a remaining amount at the time ks. η_{i, j}^{chg} is a constant representing an efficiency related to charging (that satisfies 0<η_{i, j}^{chg}≦1) η_{i, j}^{dchg} is a constant representing an efficiency related to discharging (that satisfies 0<η_{i, j}^{dchg}≦1).

Herein, a time length for which charging/discharging is performed within the segment k will be defined as in (5).

$$\begin{matrix}{τ}_{i , j}^{chg} [ k ] \text{:} a time length for which charging \\ is performed within the segment k ( unit \text{:} h ) \\ {τ}_{i , j}^{dchg} [ k ] \text{:} a time length for which discharging \\ is performed within the segment k ( unit \text{:} h ) \end{matrix} \} \qquad ( 5 )$$

With this definition, the following relational Expression (6) is established.

τ_{i,j}^{chg}[k]+τ_{i,j}^{dchg}[k≦T (6)

In addition, based on the definition of α_{i, j}, β_{i, j}, the following Expression (7) is established.

$$\begin{matrix}{u}_{i , j}^{chg} [ k ] = {α}_{i , j} {τ}_{i , j}^{chg} [ k ] \\ {u}_{i , j}^{dchg} [ k ] \leq {β}_{i , j} {τ}_{i , j}^{dchg} \end{matrix} \} \qquad ( 7 )$$

Based on an expression obtained by multiplying α_{i, j}β_{i, j} with both sides of the above-described relational Expression (6) and on the Expression (7), it is possible to obtain the seventh formula in the Expression (4).

Note that u_{i, j}^{chg} (t), u_{i, j}^{dchg} (t), y_{i, j}^{exp} (t) on the storage battery system 30 have a constraint as illustrated in the following Expression (8).

u_{i, j}^{chg}(t)=α or 0, u_{i, j}^{dchg}(t)≦β_{i,j}, y_{i,j}^{exp}(t)≦μ_{i,j} (8)

Regarding the time of charging (charging and bypass) on the storage battery system 30, the following Expression (9) is established.

$$\begin{matrix}{u}_{i , j}^{chg} ( t ) = α \\ {u}_{i , j}^{+} ( t ) = {η}_{i , j}^{chg} {u}_{i , j}^{chg} ( t ) = {η}_{i , j}^{chg} α\end{matrix} \} \qquad ( 9 )$$

Regarding the time of discharging on the storage battery system 30, the following Expression (10) is established.

$$\begin{matrix}{u}_{i , j}^{dchg} ( t ) = {η}_{i , j}^{dchg} {u}_{i , j}^{-} ( t ) \\ {y}_{i , j}^{exp} ( t ) = {u}_{i , j}^{dchg} ( t ) - {ɛ}_{i , j}\end{matrix} \} \qquad ( 10 )$$

The model expression when the type of node (i, j) is the electric appliance 50 (load) is as illustrated in the following Expression (11). “M” in the Expression (11) is any positive constant.

c_{i,j}=0,η_{i,j}^{chg}=1,η_{i,j}^{dchg}=1,α_{i,j}=M,β_{i,j}=0,x_{i,j}^{s}=0 (11)

At this time, ε_{i, j}, μ_{i, j} is as illustrated in Expression (12).

ε_{i,j}0,μ_{i,j}=0 (12)

The model expression when the type of node (i, j) is the distribution panel 20 is as illustrated in the following Expression (13).

c_{i,j}=0,η_{i,j}^{chg}=1,η_{i,j}^{dchg}=1,α_{i,j}=0,x_{i,j}^{s}=0 (13)

It is assumed that the charge command at the node (i, j) is determined as s_{i, j}^{chg} (t), and the discharge command as s_{i, j}^{dchg} (t). At the node (i, j), the power value to be used for charging when the charge command is issued is as illustrated in the following Expression (14).

u_{i,j}^{chg}(t)=α_{i,j}s_{i,j}^{chg}(t) (14)

At the node (i, j), the power value to be discharged when the discharge command is issued is as illustrated in the following Expression (15).

u_{i,j}^{dchg}(t)=w_{i,j}(t)+y_{i,j}^{exp}(t))s_{i,j}^{dchg}(t) (15)

Notation that indicates summation is as illustrated in the following (16).

$$\begin{matrix}F ( i , j ) is assumed to be a conditional \\ expression related to ( i , j ) ∈ N . \\ It is assumed that \\ [ Formula ] \\ is determined with respect to an arbitrary ( i , j ) \\ {ξ}_{i , j} ∈ R \\ At this time , \\ {\sum }_{i , j \text{:} F ( i , j )} {ξ}_{i , j} \\ represents a sum of \\ {ξ}_{i , j} ∈ R \\ for all ( i , j ) ∈ N that satisfy F ( i , j ) . \\ When \\ \{ ( i , j ) ∈ N \text{:} F ( i , j ) = 0 \} , \\ {\sum }_{i , j \text{:} F ( i , j )} {ξ}_{i , j} = 0 \\ is established . \\ Note that \\ {\sum }_{i , j \text{:} ( i , j ) ∈ N} {ξ}_{i , j} \\ can be abbreviated as \\ {\sum }_{( i , j ) ∈ N} {ξ}_{i , j} \end{matrix} \} \qquad ( 16 )$$

The power demand amount will be defined as in the following (17).

$$\begin{matrix}The amount of power demand for the segment k \\ estimated at time ks is represented as \text{:} \\ {D}^{⋒} [ k \vert {k}_{s} ] \\ On the other hand , the amount of power demand in \\ practice for the segment k till the time ks is represented as \text{:} \\ \breve{D} [ k \vert {k}_{s} ] \\ D [ k \vert {k}_{s} ] is defined as follows \text{:} \\ D [ k \vert {k}_{s} ] \text{:} = \{ \begin{matrix}\breve{D} [ k \vert {k}_{s} ] , for k = 0 , … , {k}_{s} - 1 \\ {D}^{⋒} [ k \vert {k}_{s} ] , for k = 0 , … , {k}_{e} - 1\end{matrix} \end{matrix} \} \qquad ( 17 )$$

The calculation unit 133b solves an optimization problem in which a value with a weight (ρ) is determined as a minimum value in the following Expression (18) in relation with the amount of peak power amount (P), the total remaining amount (C) at a final time, and a total power demand amount (G) in a target range (the electric appliance 50 within a system).

ρPP+ρCC+ρGG (18)

Constraints for solving the optimization problem, about the node (i, j), is as illustrated in the following Expression (19). For P, C, and G, the constraints are as illustrated in the following Expression (20).

$$\begin{matrix}\begin{matrix}{x}_{i , j} [ k + 1 ] = {x}_{i , j} [ k ] + {u}_{i , j}^{+} [ k ] - {u}_{i , j}^{-} [ k ] \\ ⋮ \\ {u}_{i , j}^{+} [ k ] = {η}_{i , j}^{chg} {u}_{i , j}^{chg} [ k ] \\ {u}_{i , j}^{dchg} [ k ] = {η}_{i , j}^{dchg} {u}_{i , j}^{-} [ k ] \\ ⋮ \\ {y}_{i , j}^{exp} [ k ] = {\sum }_{l , m \text{:} {n}_{l , m} ∈ {e}_{i , j}} {y}_{l , m}^{imp} [ k ] \end{matrix} \} & ( 19 ) \\ \begin{matrix}\breve{P} = {max}_{0 \leq k \leq {k}_{s} - 1} D [ k \vert {k}_{s} ] \\ \breve{P} = {max}_{{k}_{s} \leq k \leq {k}_{e} - 1} \{ D [ k \vert {k}_{s} ] - {\sum }_{( i , j ) ∈ N} {ɛ}_{i , j} + {y}_{0 , 1}^{imp} [ k ] ) \\ P = max \{ \breve{P} , {P}^{⋒} \} \\ C = - {\sum }_{( i , j ) ∈ N} {x}_{i , j} [ {k}_{e} ] \\ G = {\sum }_{k = {k}_{s}}^{{k}_{e}} {y}_{0 , 1}^{imp} [ k ] \end{matrix} \} & ( 20 )\end{matrix}$$

The calculation unit 133b solves the above-described optimization problem, thereby calculating the amount of charging/discharging of each of the storage battery systems 30 in the segment K.

The determination unit 133c, based on the amount of charging/discharging of each of the storage battery systems 30 for each of time segments calculated by the calculation unit 133b, determines the charge timing and the discharge timing of each of the storage battery systems 30 for each of the time segments. Specifically, the determination unit 133c determines the charge timing and the discharge timing such that each of power constraints (for example, the rated output power value, the rated power consumption value, and the full charge capacity) on each of the storage battery systems 30 are satisfied and, at the same time, the amount of charging/discharging of the real number value calculated by the calculation unit 133b is achieved as much as possible. As described above, by configuring to determine the charge timing and discharge timing so as to satisfy the power constraint, it is possible, for example, to achieve stable operation within a rated range.

The charge timing and the discharge timing of each of the storage battery systems 30 are thus determined by the determination unit 133c in each of the time segments. The creation unit 133 then stores the determined charge timing and the discharge timing in the control scheme table 125.

The charge timing and the discharge timing of each of the storage battery systems 30 in each of the time segments thus stored in the control scheme table 125 are, then, output to the storage battery system 30 that is identified with ID, by the output unit 134, via the communication control unit 110.

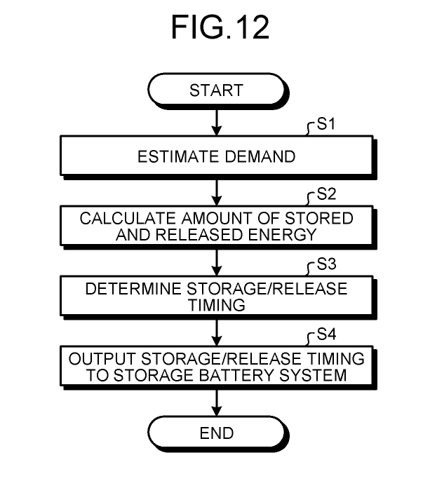

FIG. 12 is a flowchart of exemplary operation of the control server 100 according to an embodiment. As illustrated in FIG. 12, when processing is started, the demand estimation unit 133a performs estimation of the power demand amount within a system (S1) for each of the time segments in system operation time (starting time to ending time). The calculation unit 133b subsequently calculates (S2) the amount of energy of stored and released power (the amount of charging/discharging) in each of the storage battery systems 30 across each of the time segments of the operation time based on the estimation value of power demand amount calculated by the demand estimation unit 133a and based on the remaining amount of each of the storage battery systems 30 stored in the remaining amount data 123. Subsequently, the determination unit 133c determines the store and release timing (the charge timing and the discharge timing) of each of the storage battery systems 30 in each of the time segments (S3) based on the amount of stored and released energy of power in each of the storage battery systems 30, that has been calculated for each of the time segments. Subsequently, the output unit 134 outputs the storage and release timing of each of the storage battery systems 30 in each of the time segments, determined by the determination unit 133c, to each of the storage battery systems 30 (S4).

With this configuration, timing of charging and discharging in a time segment is controlled on each of the storage battery systems 30. Accordingly, operation of the storage battery system 30 in each of the time segments is not limited to any one of charge/discharge/bypass operation, making it possible to efficiently utilize the capabilities of the storage battery 32.

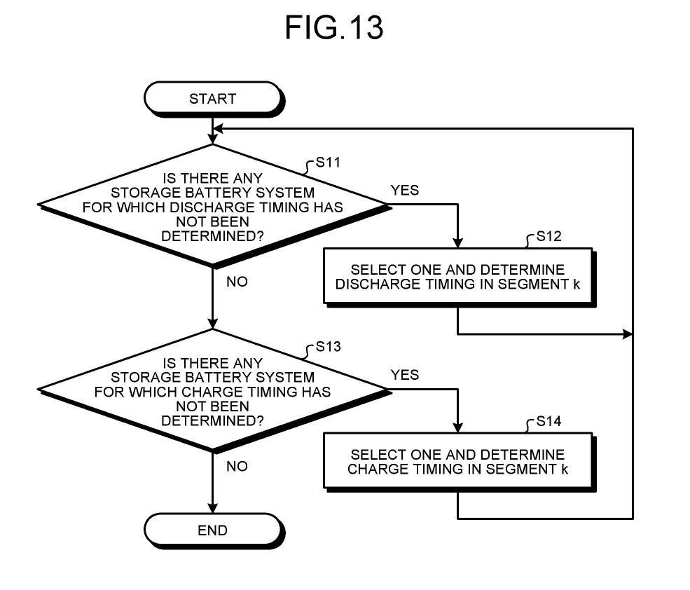

Detailed processing of determining the charge timing and discharge timing executed on the determination unit 133c will be described. FIG. 13 is a flowchart of exemplary processing of determining charge timing and discharge timing.

As illustrated in FIG. 13, when the determination processing is started, the determination unit 133c determines whether there is a storage battery system 30 for which the discharge timing has not been determined, among the plurality of storage battery systems 30 (S11). Specifically, in S11, the determination unit 133c determines whether there is a storage battery system 30 for which the discharge timing has not been determined among the storage battery systems 30 being connected solely with the storage battery system 30 for which the charge timing and the discharge timing for the storage battery system 30 have been determined within the segment K”. For example, the determination unit 133c examines a node connection relationship based on a node index, and extracts a storage battery system 30 to which a node for which the charge timing and the discharge timing have been determined within the segment K is connected downstream. The determination unit 133c subsequently determines among the extracted storage battery systems 30, whether there is a storage battery system 30 for which the discharge timing has not been determined.

The electric appliance 50 (load) is assumed to be a node for which the charge timing and the discharge timing have been determined. With this configuration, the first processing extracts, among the plurality of storage battery systems 30, the storage battery system 30 that is not connected with any storage battery system 30 downstream and that is connected with the electric appliance 50 (load) downstream, or extracts a storage battery system such as a notebook PC that consumes power on its own device. With a progress in processing, extraction is performed in the above-described tree structure in an order such that the storage battery system 30 that has closer connection relationship to the electric appliance 50 (load) is extracted first.

When there is the storage battery system 30 that is relevant in S11, the determination unit 133c selects one from the relevant storage battery system 30 and determines the discharge timing in the segment K (S12) and returns processing to S11.

If there is no relevant storage battery system 30 in S11, the creation unit 133 determines whether there is a storage battery system 30 for which the charge timing has not been determined among the plurality of storage battery systems 30 (S13). Specifically, in S13, the determination unit 133c determines whether there is a storage battery system 30 for which the charge timing has not been determined among “the storage battery systems 30 being connected solely with the storage battery system 30 for which the charge timing and the discharge timing for the storage battery system 30 have been determined within the segment K”. For example, the determination unit 133c examines a node connection relationship based on a node index, and extracts a storage battery system 30 to which a node for which the charge timing and the discharge timing have been determined within the segment K is connected downstream. The determination unit 133c subsequently determines among the extracted storage battery systems 30, whether there is a storage battery system 30 for which the charge timing has not been determined.

The electric appliance 50 (load) is assumed to be a node for which the charge timing and the discharge timing have been determined. With this configuration, the first processing extracts, among the plurality of storage battery systems 30, the storage battery system 30 that is not connected with any storage battery system 30 downstream and that is connected with the electric appliance 50 (load) downstream. With a progress in processing, extraction is performed in the above-described tree structure in an order such that the storage battery system 30 that has closer connection relationship to the electric appliance 50 (load) is extracted first.

If there is the storage battery system 30 that is relevant in S13, the determination unit 133c selects one from the relevant storage battery system 30 and determines the charge timing in the segment K (S14) and returns processing to S11.

The storage battery system 30 for which the discharge timing and the charge timing have been determined can be estimated as a similar component as the electric appliance 50 (load) when the control scheme is created. Accordingly, to determine the discharge timing and the charge timing as described above is to facilitate determination of the discharge timing and the charge timing. As a result of utilizing this procedure for determination, extraction is performed in the tree structure in an order such that the storage battery system that has the closest relationship in connection to the electric appliance 50 (load) is extracted first. From the viewpoint of classification of the optimization problem, determination of the charge timing and the discharge timing can be classified into a type of cutting and packing problems that has a structure that, by starting with the storage battery system 30 to which the electric appliance 50 alone is connected, solving one small problem leads to determination of a next small problem. With this structure, it is possible to settle processing in a shorter time.

Moreover, as in the above-described processing, the control server 100, when it determines that there is no storage battery system 30 for which discharge timing has not been determined (S11: NO), performs determination of charge timing (S14). This means charge timing is determined after discharge timing has been determined. With this configuration, in a case where the discharge timing has been determined in many of the storage battery systems 30 at determination of the charge timing, it is possible to easily calculate the charge timing that achieves the amount of charging/discharging calculated by the calculation unit 133b while satisfying the power constraint.

Determination of the discharge timing and the charge timing will be described in detail.

First, for 0≦τ<T, y_{i, j}^{exp} [k] (τ) will be defined as in the following Expression (21).

$${y}_{i , j}^{exp} \{ k ] ( τ ) = - {\sum }_{l , m \text{:} {n}_{l , m} ∈ {D}_{i , j}} {ɛ}_{l , m} \qquad ( 21 )$$

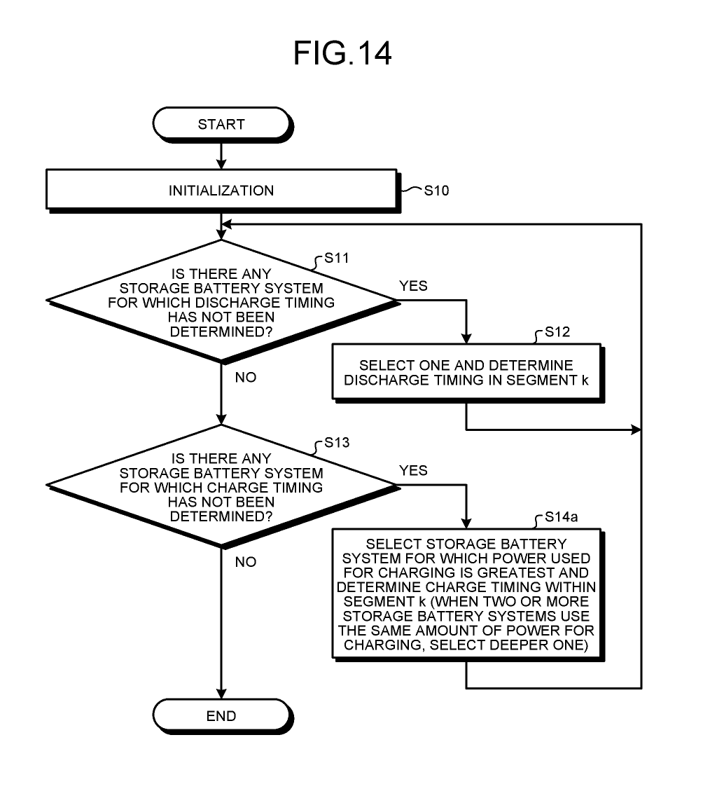

The Expression (21) represents operation of initialization (S10 in FIG. 14) that sets an initial value of output at each of the nodes to a value that would be achieved in a case where all the storage battery systems 30 perform bypass operation.

Determination of the discharge timing will be described. First, in determination of the discharge timing, there is a case where the following Expression (22) is satisfied.

∫₀^{T}(y_{i,j}^{exp}[k](τ)+ε_{i,j})dτ≧u_{i,j}^{dchg}[k] (22)

The case where this Expression (22) is satisfied is a case where discharging across all portions of the segment K leads to a possibility of discharging the amount of power that is equal to or more than the amount allocated to that segment. In this case, r_{i, j}[k] is defined as in the following (23).

r_{i,j}[k]: an element of [0, T)that satisfies the formula ∫ᵣ_{_{i,j}}_{[k]}^{T}(y_{i,j}^{exp}[k](τ)+ε_{i,j})dτ” (23)

In addition, s_{i, j}^{dchg}|_{[kt, k+1)T)} (t), namely, s_{i, j}^{dchg} (t) within the segment K, will be determined as in the following Expression (24). In Expression (24), a conditional expression of t related to s_{i, j}^{dchg} (t)=1 defines (determines) the starting time and ending time of discharging within the segment K.

$${s}_{i , j}^{dchg} {\vert}_{[ kT , ( k + 1 ) T )} ( t ) = \{ \begin{matrix}0 , kT \leq t < kT + {r}_{i , j} [ k ] \\ 1 , kT + {r}_{i , j} [ k ] \leq t < ( k + 1 ) T\end{matrix} \qquad ( 24 )$$

Expressions (23) and (24) correspond to a scheme (for discharge timing) in which discharging up to the time (k+1)T is executed to discharge the allocated amount of power (the value calculated by the calculation unit 133b).

In addition, for 0≦τ<T, u_{i, j}^{dchg} [k](τ) will be defined as in the following Expression (25).

$${u}_{i , j}^{dchg} [ k ] ( τ ) \text{:} = \{ \begin{matrix}0 , & 0 \leq τ < {r}_{i , j} [ k ] \\ {y}_{i , j}^{exp} [ k ] ( τ ) + {ɛ}_{i , j} & {r}_{i , j} [ k ] \leq τ < T\end{matrix} \qquad ( 25 )$$

Moreover, for all nodes (l, m) that satisfy node (l, m) ∈ set A_{i, j} (set of all ancestor nodes), y_{l, m}^{exp} [k] (τ) is updated as in the following Expression (26).

y_{l,m}^{exp}[k](τ)←y_{l,m}^{exp}[k](τ)−u_{i,j}^{dchg}[k](τ) (26)

Expressions (25) and (26) correspond to operation of updating an output value of the ancestor node of the node (i, j) to a value that incorporates effects of the discharge timing that has just been determined.

In addition, in determination of the discharge timing, there is a case where the following Expression (27) is satisfied.

∫₀^{T}(y_{i,j}^{exp}[k](τ)+ε_{i,j})dτ<u_{i,j}^{dchg}[k] (27)

The case where Expression (27) is satisfied is a case where even when discharging is performed across all portions of the segment K, it is not possible to discharge the amount of power allocated to the segment. In this case, it is configured to determine s_{i, j}^{dchg}|_{[kT,(k+1)T)} (t), namely, s_{i, j}^{dchg} (t) in the segment K, as in the following Expression (28).

s_{i,j}^{dchg}(t)|[kT,(k+1)T)=1 (28)

Expression (28) corresponds to a scheme (for discharge timing) for achieving an allocated value (value calculated by the calculation unit 133b) as much as possible.

In addition, for 0≦τ<T, u_{i, j}^{dchg} [k] (τ) will be defined as in the following Expression (29).

u_{i,j}^{dchg}[k](τ):=y_{i,j}^{exp}[k](τ)+ε_{i,j} (29)

Moreover, for all nodes (l, m) that satisfy node (l, m) ∈ set A_{i, j} (set of all ancestor nodes), Y_{l, m}^{exp} [k] (τ) is updated as in the following Expression (30).

y_{l,m}^{exp}[k](τ)←y_{l,m}^{exp}[k](τ)−u_{i,j}^{dchg}[k](τ) (30)

Expressions (29) and (30) correspond to operation of updating an output value of the ancestor node of the node (i, j) to a value that incorporates effects of the discharge timing that has just been determined.

Next, determination of the charge timing will be described. First, in determination of the charge timing, for 0≦τ<T, z_{i, j, l, m} [k] (τ) is defined as in the following (31). Note that node (l, m) ∈ set A_{i, j} (set of all ancestor nodes) holds.

z_{i,j,l,m}[k](τ):=μ_{i,m}−(y_{l,m}^{exp}[k](τ)+α_{i,j}) (31)

In addition, s_{i, j, l, m} [k] is defined as in the following (32).

$${S}_{i , j , l , m} [ k ] \text{:} = {supp}_{\geq 0} ( {z}_{i , j , l , m} [ k ] )$$

$$[ \begin{matrix}Herein , with respect to the formula \text{:} \\ f \text{:} D \to R \\ τ ↦ f ( τ ) \\ the sign supp \geq 0 ( f ) is defined as follows \text{:} \\ {supp}_{\geq 0} ( f ) \text{:} = \{ τ ∈ D \vert f ( τ ) \geq 0 \} \end{matrix} ] \qquad ( 32 )$$

s_{i, j, l, m} [k] obtained in (31) and (32) is a set at a time point that even when the node (i, j) is charged, a constraint related to the output power of the node (l, m) would not be violated.

s_{i, j} [k] is defined as the following (33).

$${S}_{i , j} [ k ] \text{:} = {⋂}_{l , m \text{:} {n}_{l , m} ∈ {u}_{i , j}} {S}_{i , j , l , m} [ k ] \qquad ( 33 )$$

s_{i,j}, [k] obtained in (33) is a set of time points that even when the node (i, j) is charged, a constraint related to the output power would not be violated upstream of the node.

After preparing the above-described (31) to (33), the charge timing is determined. In determination of the charge timing, there is a case where the following Expression (34) is satisfied.

$$ϕ ( {S}_{i , j} [ k ] ) \geq \frac{{u}_{i , j}^{chg} [ k ]}{{α}_{i , j}} \qquad ( 34 )$$

The case where Expression (34) is satisfied is a case where discharging across all of chargeable time zones within the segment K leads to a possibility of charging equal to or more than the amount allocated to the segment. In this case, p_{i, j} [k], q_{i, j} [k], and c_{i, j} [k] are defined as in the following (35). Herein, φ represents the Lebesgue measure.

$$\begin{matrix}{p}_{i , j} [ k ] \text{:} = {min}_{τ ∈ {S}_{i , j} [ k ]} τ \\ {q}_{i , j} [ k ] \text{:} = “ an element of [ 0 , T ) that satisfies ϕ ( {S}_{i , j} ⋂ [ {p}_{i , j} [ k ] , {q}_{i , j} [ k ] ] ) = \frac{{u}_{i , j}^{chg} [ k ]}{{α}_{i , j}} \\ ” \\ {C}_{i , j} [ k ] \text{:} = {S}_{i , j} [ k ] ⋂ [ {p}_{i , j} [ k ] , {q}_{i , j} [ k ] ) \end{matrix} \} \qquad ( 35 )$$

s_{i, j}^{chg}|_{[kT, (k+1)T]} (t), namely, s_{i, j}^{chg} (t) within the segment K is determined as in the following Expression (36). In Expression (36), a conditional expression of t related to s_{i, j}^{chg} (t)=1 defines (determines) the starting time and the ending time of charging within the segment K.

$${s}_{i , j}^{chg} {\vert}_{[ kT , ( k + 1 ) T )} ( t ) = \{ \begin{matrix}0 , kT \leq t < ( k + 1 ) T , t - kT ∉ {C}_{i , j} [ k ] \\ 1 , kT \leq t < ( k + 1 ) T , t - kT ∈ {C}_{i , j} [ k ]\end{matrix} \qquad ( 36 )$$

Expressions (35) and (36) correspond to a scheme (for charge timing) for completing charging of the allocated amount of power (a value calculated by the calculation unit 133b) at a point as close to the kT as possible.

For 0≦τ<T, u_{i, j}^{chg} [k] (τ) will be defined as in the following Expression (37).

$${u}_{i , j}^{chg} [ k ] ( τ ) = \{ \begin{matrix}0 , & τ ∉ {C}_{i , j} [ k ] \\ {α}_{i , j} & τ ∈ {C}_{i , j} [ k ]\end{matrix} \qquad ( 37 )$$

Moreover, for all nodes (l, m) that satisfy node (l, m) ∈ set A_{i, j} (set of all ancestor nodes), y_{l, m}^{exp} [k] (t) is updated as in the following Expression (38).

y_{l,m}^{exp}[k](τ)←y_{l,m}^{exp}[k](τ)−u_{i,j}^{dchg}[k](τ) (38)

Expressions (37) and (38) correspond to operation of updating an output value of the ancestor node of the node (i, j) to a value that incorporates effects of the charge timing that has just been determined.

In determination of the charge timing, there is a case where the following Expression (39) is satisfied.

$$ϕ ( {s}_{i , j} [ k ] ) < \frac{{u}_{i , j}^{chg} [ k ]}{{α}_{i , j}} \qquad ( 39 )$$

The case where Expression (39) is satisfied is a case where even when charging is performed across all of the chargeable time zones of the segment K, it is not possible to charge the amount of power allocated to the segment. In this case, C_{i, j} is defined as in the following (40).

C_{i,j}[k]:=S_{i,j}[k] (40)

s_{i, j}^{chg}|_{[kT, (k+1)T)} (t) , namely, s_{i, j}^{chg} (t) within the segment K is determined as in the following Expression (41).

$${s}_{i , j}^{chg} {\vert}_{[ kT , ( k + 1 ) T )} ( t ) = \{ \begin{matrix}0 , kT \leq t < ( k + 1 ) T , t - kT ∉ {C}_{i , j} [ k ] \\ 1 , kT \leq t < ( k + 1 ) T , t - kT ∈ {C}_{i , j} [ k ]\end{matrix} \qquad ( 41 )$$

Expression (41) corresponds to a scheme (for charge timing) for achieving an allocated value (value calculated by the calculation unit 133b) as much as possible.

In addition, for 0≦τ<T, u_{i, j}^{chg} [k] (t) will be defined as in the following Expression (42).

$${u}_{i , j}^{dchg} [ k ] ( τ ) = \{ \begin{matrix}0 , & τ ∉ {C}_{i , j} [ k ] \\ {α}_{i , j} & τ ∈ {C}_{i , j} [ k ]\end{matrix} \qquad ( 42 )$$

Moreover, for all nodes (l, m) that satisfy node (l, m) ∈ set Ai, ⱼ (set of all ancestor nodes), y_{l, m}^{exp} [k] (τ) is updated as in the following Expression (43).

y_{l,m}^{exp}[k](τ)←y_{l,m}^{exp}[k](τ)+u_{i,j}^{chg}[k](τ) (43)

Expressions (42) and (43) correspond to operation of updating an output value of the ancestor node of the node (i, j) to a value that incorporates effects of the charge timing that has just been determined.

Another example of processing of determining the charge timing and the discharge timing will be described. FIG. 14 is a flowchart of exemplary processing of determining the charge timing and the discharge timing.

As illustrated in FIG. 14, when the determination processing is started, the determination unit 133c performs initialization (S10). The operation of initialization is as illustrated in the above-described Expression (21) that corresponds to the operation of setting the initial value of the output of each of the nodes to the value when all of the storage battery systems 30 would perform bypass operation.

The determination unit 133c performs processing in S11 to S13 in a similar manner as in the above-described procedure. When there is a relevant storage battery system 30 in S13, the determination unit 133c selects, from among the relevant storage battery systems 30, the storage battery system 30 for which the power used for charging is greatest (with the greatest value α_{i, j}), determines the charge timing within the segment K (S14a), and returns the processing to S11. Note that, when two or more storage battery systems use the same amount of power for charging in S14a, it is configured, based on the index, to select the deeper one in the tree structure.

By determining the charge timing for the storage battery system 30 in the order of greatness of power used for charging, it is possible to perform adjustment, in later processing, by using the system for which power used for charging is smaller. Accordingly, it is possible to control charging/discharging to be close to the amount of charging/discharging that is a real number value calculated by the calculation unit 133b.

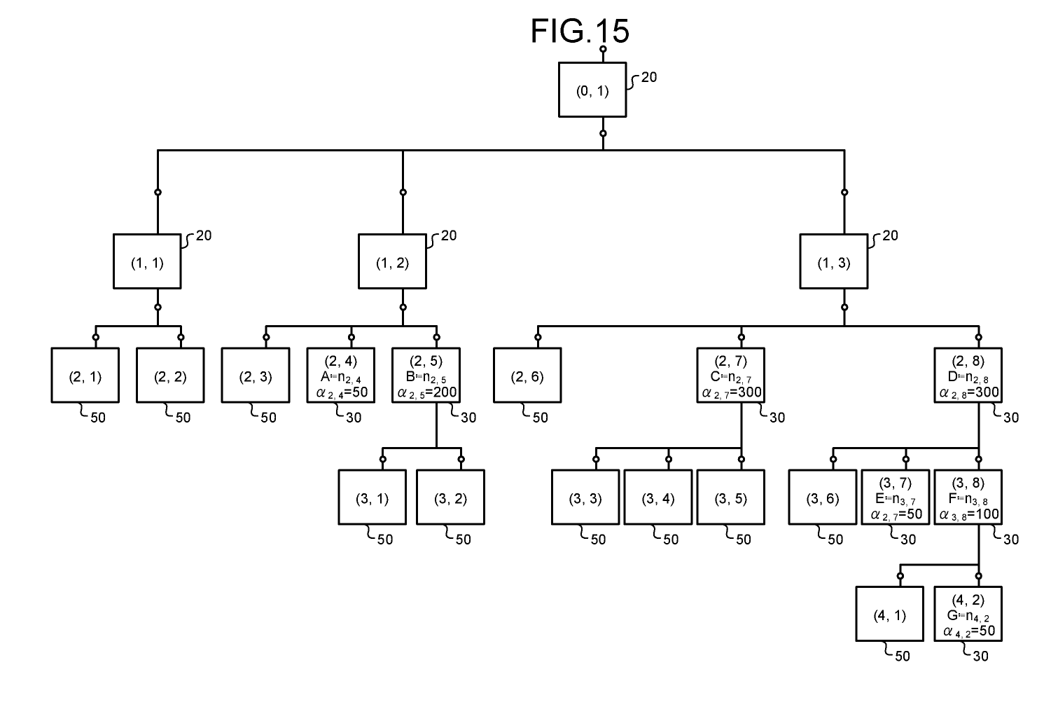

With a more specific example, processing of determining the charge timing and the discharge timing will be described. FIG. 15 is an exemplary diagram of a node connection configuration.

As illustrated in FIG. 15, the node connection configuration related to the distribution panel 20, the storage battery system 30, and the electric appliance 50 is similar to the example in FIG. 7. What differs is that each of the storage battery systems 30 at each of nodes (2,4), (2,5), (2,7), (2,8), (3,7), (3,8), and (4,2) has another name of A, B, C, D, E, F, and G, respectively. The power (α_{i, j}) used for charging each of A, B, C, D, E, F, and G is to be as A:50, B:200, C:300, D:300, E:50, F:100, and G:50, respectively.

Sets related to determination of S11 and S13 are defined as in the following (44).

$$\begin{matrix}{S}^{dchg} [ k ] \text{:} & A set of all of “ storage battery systems for which the discharge timing \\ & has not been determined among ‘ the storage battery systems being connected \\ & solely with the storage battery system for which the charge timing and the \\ & discharge timing for the storage battery system area determined within \\ & the segment k ’ ” \\ {S}^{chg} [ k ] \text{:} & A set of all of “ storage battery systems for which the charge timing has not \\ & been determined amount ‘ the storage battery systems being connected solely \\ & with the storage battery system for which the charge timing and the discharge \\ & timing for the storage battery system are determined with the segment k ’ ” \end{matrix} \} \qquad ( 44 )$$

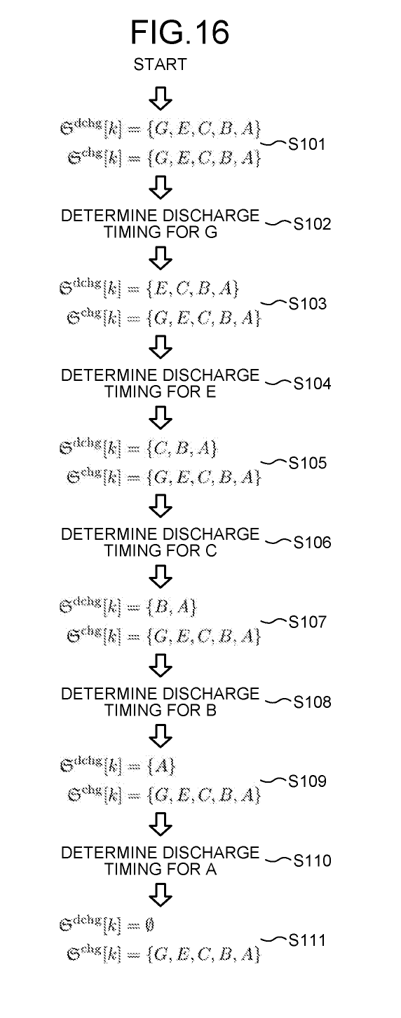

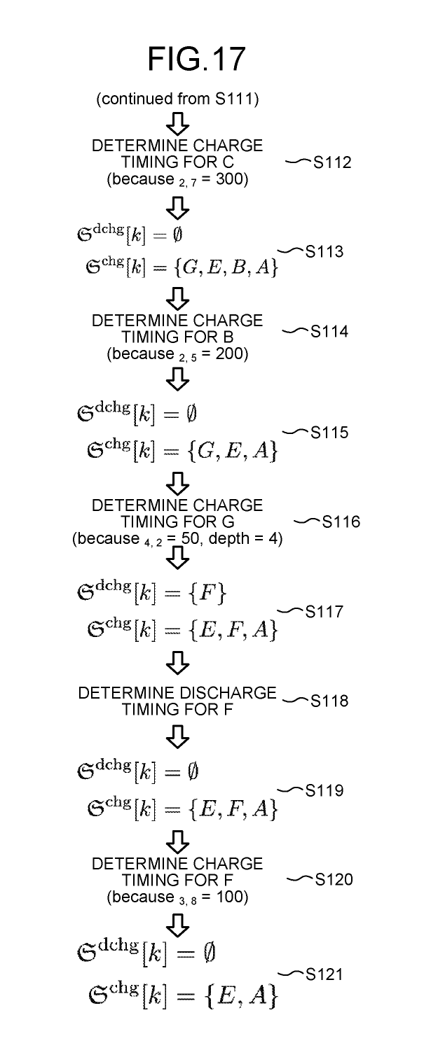

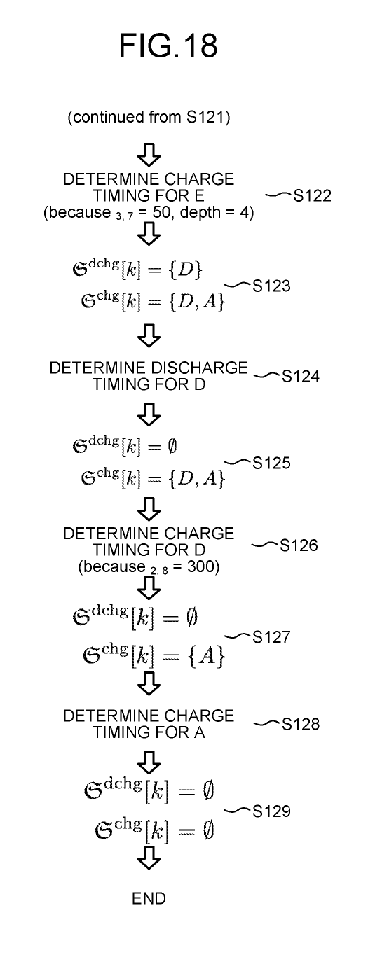

FIG. 16 is an illustration of a flow of determining the charge timing and the discharge timing. FIG. 17 is an illustration of a flow continuing from the flow in FIG. 16. FIG. 18 is an illustration of a flow continuing from the flow in FIG. 17.

As illustrated in FIG. 16, elements of the set defined in (44) after start of processing are as illustrated in S101.

Next, in S12, that is after determination of YES in S11, the discharge timing is determined for G at an end of the tree structure (S102). Elements of the set after S102 are illustrated in S103. Thereafter, the discharge timing of each of the storage battery systems 30 is determined sequentially beginning from the downstream side (S104 to S110).

Elements of the set after S110 is as illustrated in S111. When there is a storage battery system 30 for which the discharge timing has not been determined among “the storage battery systems 30 being connected solely with the storage battery system 30 for which the charge timing and the discharge timing for the storage battery system 30 have been determined within the segment K”, the result would be empty.

Hereafter, in S14a after determination of YES in S13, the charge timing is determined for the storage battery system 30 in the order of greater value α (S112 to S115). For α=50, A, E, and G are relevant. Among these, G, which is the deepest, is selected and the discharge timing for G is determined (S116).

Determination of the discharge timing for G causes F to be included in a set in which discharge timing has not been determined, among “the storage battery systems 30 being connected solely with the storage battery system 30 for which the charge timing and the discharge timing for the storage battery system 30 have been determined within the segment K” (S117). Accordingly, in S12 after determination of YES in S11, the discharge timing of F is determined (S118). In this manner, the charge timing and the discharge timing are sequentially determined (S119 to S128), and the processing is finished when the set defined in (44) becomes empty (S129).

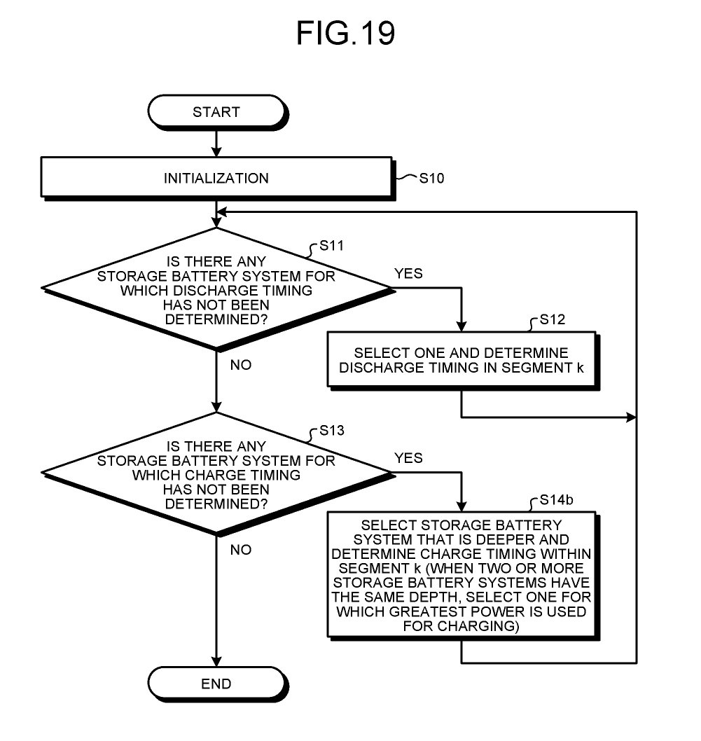

In determination of the charge timing in S14a, the deeper one in the tree structure may have higher priority than the one for which greater power is used for charging. FIG. 19 is a flowchart of exemplary processing of determining the charge timing and the discharge timing.

As illustrated in FIG. 19, when there is a relevant storage battery system 30 in S13, the determination unit 133c selects the storage battery system 30 that is deeper in the tree structure from among the relevant storage battery systems 30, based on the index, determines the charge timing within the segment K (S14b), and returns the processing to S10. Note that, in S14b, when two or more storage battery systems have the same depth, it is configured to select the one for which greatest power is used for charging (with the greatest value α_{i, j}).

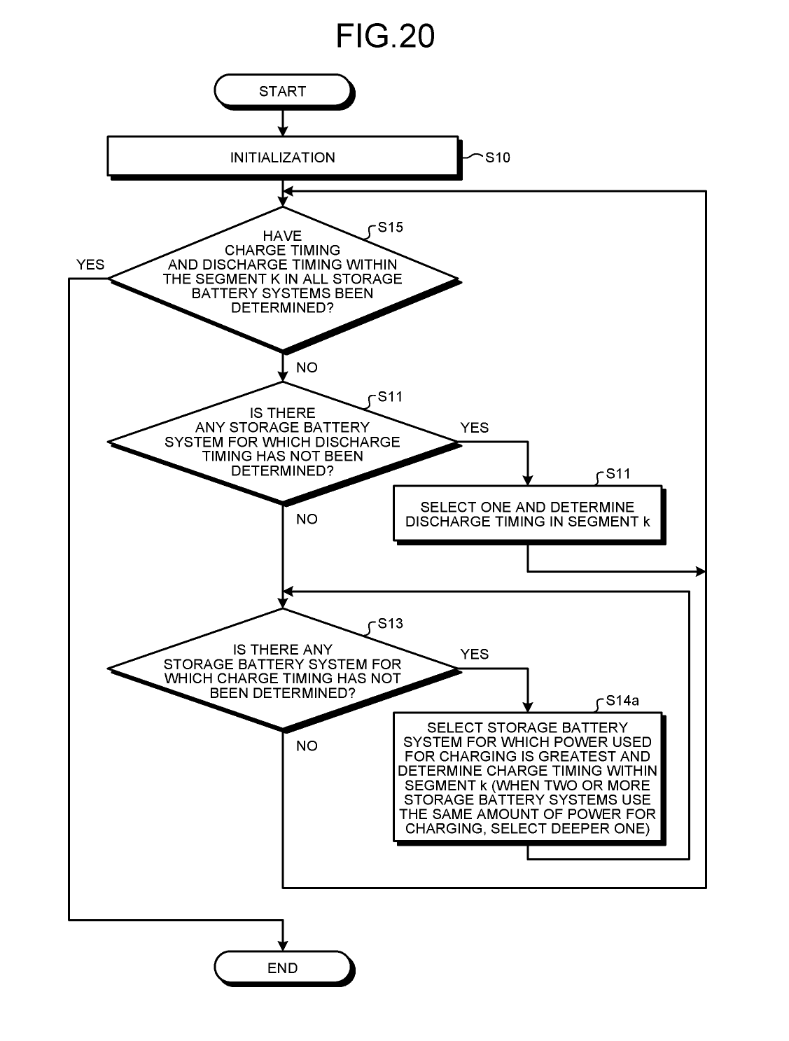

FIG. 20 is a flowchart of exemplary processing of determining the charge timing and the discharge timing. As illustrated in FIG. 20, the determination unit 133c may determine, after initialization (S10), whether the charge timing and the discharge timing within the segment K in all the storage battery systems 30 have been determined (S15). When the determination is YES, the determination unit 133c finishes the processing, thereby suppressing inadvertent continuation of a processing loop.

The present embodiment has described an exemplary storage battery system, as an example of the energy storage device that stores energy and releases stored energy. Note that any energy storage device may be used as long as it can control storing and releasing of energy. The configuration, thus, is not limited to the storage battery system. Energy storage devices other than the storage battery system include a capacitor, a flywheel, and a heat storage tank. In the present embodiment, it is possible to use these energy storage devices as nodes for storing and releasing energy, and to control these devices by the control server 100.

Furthermore, each of components in each of the devices in the figures need not be physically configured as in the figures. In other words, specific forms of dispersion/integration of each of the devices are not limited to the forms in the figures. All or part of them may be configured in a functionally or physically dispersed/integrated form in an arbitrary unit, according to various loads and status of use, or the like. For example, the acquisition unit 131, the measurement unit 132, the creation unit 133 or the output unit 134 may be connected via the network 10, as an external device of the control server 100. Alternatively, it is possible to configure such that each of the acquisition unit 131, the measurement unit 132, the creation unit 133 or the output unit 134 is included in another apparatus to operate in cooperation via network connection, so as to achieve the above-described functions of the control server 100.

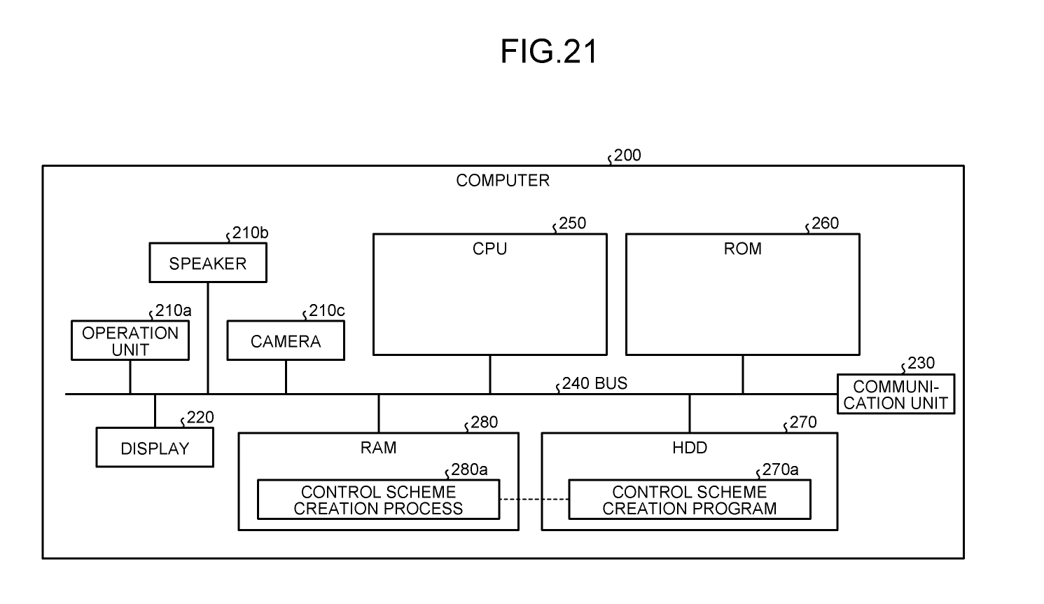

The various types of processing described in the above-described embodiments can be achieved by executing a prepared program on a computer such as a personal computer and a workstation. Hereinafter, an exemplary computer for executing a control scheme creation program having similar functions as in the above-described embodiments, with reference to FIG. 21.

FIG. 21 is an illustration of an example of a computer 200 that executes a control scheme creation program 270a. As illustrated in FIG. 21, the computer 200 includes an operation unit 210a, a speaker 210b, a camera 210c, a display 220, and a communication unit 230. In addition, the computer 200 includes a CPU 250, ROM 260, an HDD 270, and RAM 280. The components 210 to 280 are connected with each other via a bus 240.

The HDD 270 stores a control scheme creation program 270a, which has the functions similar to the functions of the acquisition unit 131, the measurement unit 132, the creation unit 133, and the output unit 134. Similarly to each of components of the acquisition unit 131, the measurement unit 132, the creation unit 133, and the output unit 134, it is possible to perform integration or separation appropriately of the control scheme creation program 270a. For example, there is no need to store all data to the HDD 270. It would be sufficient if the data needed for processing are selectively stored in the HDD 270.

The computer 200 is configured such that the CPU 250 reads the control scheme creation program 270a from the HDD 270 and expands it onto the RAM 280. With this configuration, the control scheme creation program 270a functions as a control scheme creation process 280a. The control scheme creation process 280a reads various types of data from the HDD 270 and expands the data suitably onto an own area allocated on the RAM 280, and based on the expanded various types of data, executes various types of processing. The control scheme creation process 280a includes processing executed at the acquisition unit 131, the measurement unit 132, the creation unit 133, and the output unit 134. In addition, there is no need for each of processing units virtually implemented on the CPU 250 to operate on the CPU 250. It would be sufficient if a part of the processing units needed for the processing is selectively virtually implemented.

Note that there is no need to store the above-described control scheme creation program 270a in the HDD 270 or the ROM 260 from an initial stage. For example, it is possible to configure such that each of the programs are stored in a “portable physical medium” or a flexible disk to be inserted to the computer 200 such as a FD, a CD-ROM, a DVD, a magneto optical disk, and an IC card. It is also possible to configure such that the computer 200 obtains each of the programs from any of the portable physical media and execute the program. Alternatively, it is possible to configure such that each of the programs is stored in another computer or a server apparatus that is connected to the computer 200 via a public network, an Internet, a LAN, and a WAN, and that the computer 200 obtains each of the program from these and execute the program.

According to an embodiment of the present invention, it is possible to efficiently utilize the capabilities of the energy storage device.

All examples and conditional language recited herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. A control scheme creation method comprising:
calculating an amount of stored or released energy of each of a plurality of energy storage devices for each of a plurality of periods, based on estimation value information on an amount of energy consumption within a target area and based on remaining amount information representing an amount of remaining energy of each of the plurality of energy storage devices, using a processor; and
determining storage timing or release timing for each of the energy storage devices in each of the periods based on the calculated amount of stored or released energy, using the processor.

2. The control scheme creation method according to claim 1,
wherein the determining includes determining the storage or release timing based on a constraint in energy supply from the plurality of energy storage devices.

3. The control scheme creation method according to claim 1,
wherein the determining includes determining the storage timing of each of the energy storage devices after determining release timing of each of the energy storage devices based on the calculated amount of stored or released energy.

4. The control scheme creation method according to claim 1,
wherein the determining includes determining the storage or release timing for the energy storage device in an order from the energy storage device with the greater amount of energy needed for energy storage per a certain unit time, among the plurality of energy storage devices.

5. The control scheme creation method according to claim 1,
wherein, based on node information representing an inter-node connection relationship including the plurality of energy storage devices ranging from an energy-supplying node to an energy-consuming node, the determining includes determining the storage timing or release timing for the energy storage device in an order from the energy storage device that is closer to the energy-consuming node among the plurality of energy storage devices.

6. The control scheme creation method according to claim 1,
wherein the determining includes determining a starting time and an ending time of storage or release on each of the energy storage devices.

7. A non-transitory computer-readable recording medium having stored therein a control scheme creation program that causes a computer to execute a process including:
calculating an amount of stored or released energy of each of a plurality of energy storage devices for each of a plurality of periods, based on estimation value information on an amount of energy consumption within a target area and based on remaining amount information representing an amount of remaining energy of each of the plurality of energy storage devices; and
determining storage timing or release timing for each of the energy storage devices in each of the periods based on the calculated amount of stored or released energy.

8. The non-transitory computer-readable recording medium according to claim 7,
wherein the determining includes determining the storage or release timing based on a constraint in energy supply from the plurality of energy storage devices.

9. The non-transitory computer-readable recording medium according to claim 7,
wherein the determining includes determining the storage timing of each of the energy storage devices after determining release timing of each of the energy storage devices based on the calculated amount of stored or released energy.

10. The non-transitory computer-readable recording medium according to claim 7,
wherein the determining includes determining the storage or release timing for the energy storage device in an order from the energy storage device with the greater amount of energy needed for energy storage per a certain unit time, among the plurality of energy storage devices.

11. The non-transitory computer-readable recording medium according to claim 7,
wherein, based on node information representing an inter-node connection relationship including the plurality of energy storage devices ranging from an energy-supplying node to an energy-consuming node, the determining includes determining the storage timing or release timing for the energy storage device in an order from the energy storage device that is closer to the energy-consuming node among the plurality of energy storage devices.

12. The non-transitory computer-readable recording medium according to claim 7,
wherein the determining includes determining a starting time and an ending time of storage or release on each of the energy storage devices.

13. A control scheme creation method for causing each of a plurality of energy storage devices included in a target area to execute charging or discharging, the control scheme creation method comprising:
determining a control scheme that specifies one of storage and release as operation to be executed by each of the plurality of energy storage devices for each of a plurality of periods, based on estimation value information on an amount of energy consumption within the target area and based on remaining amount information representing an amount of remaining energy of each of the plurality of energy storage devices, using a processor; and
outputting the control scheme, using the processor

14. The control scheme creation method according to claim 13, wherein the control scheme includes information that specifies an amount of stored or released energy for each of the plurality of periods.
